(19) United States
(12) Patent Application Publication
(10) Pub. No.: US 2007/0076513 A1
(43) Pub. Date: Apr. 5, 2007

(54) Decoder for memory device with loading capacitor

(76) Inventors: Nian Yang, Mountain View, CA (US); Fan Wan Lai, San Jose, CA (US); Hounien Chen, Fremont, CA (US)

Correspondence Address: LAW OFFICE OF MONICA H CHOI, P O BOX 3424, DUBLIN, OH, 430160204, US

(21) Appl. No.: 11/243,078

(22) Filed: Oct. 4, 2005

(51) Int. Cl. G11C 8/00

(52) U.S. Cl. 365/230.06; 365/185.23

(57) ABSTRACT

A decoder system for a memory device includes a high voltage pump, a high voltage switch, and a loading capacitor. The high voltage pump generates a boost voltage, and the high voltage switch couples one of the boost voltage or a low voltage to a line of the memory device. The loading capacitor is coupled to a node between the high voltage pump and the high voltage switch to minimize voltage dipping of the boost voltage.

### TECHNICAL FIELD

The present invention relates generally to memory devices, and more particularly, to minimizing voltage dipping by adding a loading capacitor at a high voltage pump that provides a boost voltage to lines of a memory device.

### BACKGROUND OF THE INVENTION

FIG. 1 shows a typical flash memory device 100 including blocks of flash memory cells. The elements of one example block 102 include an array of flash memory cells 103. An array of eight by eight flash memory cells is illustrated in the example block 102 for simplicity of illustration and description. However, a typical block would have more numerous flash memory cells.

Each flash memory cell 103 has a control gate, a drain, and a source. The control gates of all flash memory cells in one row are coupled to a same word-line. The drains of all flash memory cells in one column are coupled to a same bit-line. Thus, the example block 102 has the eight word lines WL0, WL1, . . . , and WL7 for the eight rows of flash memory cells. In addition, the example block 102 has eight bit lines coupled to eight select MOSFETs (metal oxide semiconductor field effect transistors) 104.

Furthermore, the example block 102 has a local X-decoder 106 for activating one of the word lines WL0, WL1, . . . , and WL7. For accessing one of the flash memory cells in the block 102, a selected one of the word lines WL0, WL1, . . . , and WL7 is activated when a boost voltage VPXG is applied thereon by the local X-decoder. Additionally for accessing that flash memory cell, one of the select MOSFETs 104 coupled to the drain of that flash memory cell is turned on for applying a boost voltage YBST thereon. The sources of the flash memory cells are coupled to a low supply voltage VSS.

Further referring to FIG. 1, the local X-decoder 106 applies the boost voltage VPXG on the selected one of the word lines WL0, WL1, . . . , and WL7 using controls signals GWL and NWL from a global X-decoder 108 and using eight word-line voltages VWL0, VWL1, . . . , and VWL7 from a vertical word line decoder 112.

The GWL signal indicates whether a flash memory cell within the block 102 is to be accessed for an operation such a programming, and NWL is the reverse logical state of GWL. The global X-decoder decodes block row address bits from an address sequencer (not shown) for generating GWL and NWL that are applied across a row of blocks such as 102 and 114 in FIG. 1.

The vertical word line decoder 112 decodes vertical word line address bits from the address sequencer (not shown) for generating eight word-line voltages VWL0, VWL1, . . . , and VWL7 applied across the column of blocks 102 and 116. In addition, the drain bit line boost voltage YBST is applied on the selected drain bit line across the column of blocks 102 and 116. FIG. 1 shows an array of two by two blocks for the flash memory device 100, but typical flash memory devices typically include more numerous blocks.

FIG. 2 shows an example implementation 106A of the local X-decoder 106. The local X-decoder 106A inputs the control signals GWL, NWL, VWL0, VWL1, . . . , and VWL7 from the decoders 108 and 112. The local X-decoder 106A then applies a boost voltage VPXG on one of the word lines WL0, WL1, . . . , and WL7 when GWL is a logical high state.

Referring to FIG. 2, the local X-decoder 106A includes a respective driver for each of the word lines WL0, WL1, . . . , and WL7. Thus, a first driver 120 is for the first word line WL0, a second driver 121 is for the second word line WL1, . . . , and so on until an eighth driver 127 is for the eighth word line WL7.

Each driver, such as the first driver 120, includes a driving NMOSFET (N-channel metal oxide semiconductor field effect transistor) 132 and a pull-down NMOSFET 134 coupled in series. The driving NMOSFET 132 has a drain coupled to a corresponding line voltage VWL0 from the vertical word line decoder 112. Thus, the driving NMOSFET within the second driver 121 is coupled to the corresponding line voltage VWL1, and so on until the driving NMOSFET within the eighth driver 127 is coupled to the corresponding line voltage VWL7.

Further in the example driver 120, the source of the driving NMOSFET 132 is coupled to a drain of the pull-down NMOSFET 134. The source of the pull-down NMOSFET 134 is coupled to a low voltage VSS. The control signal NWL from the global X-decoder 108 is coupled to the gate of the pull-down NMOSFET 134. The example driver 120 also includes a pass NMOSFET 136 having a source coupled to the gate of the driving NMOSFET 132 at a control node 138.

Further referring to FIG. 2, each of the drivers 120, 121, . . . , and 127 is implemented similarly with a respective pass NMOSFET, a respective driving NMOSFET, and a respective pull-down NMOSFET. The GWL control signal from the global X-decoder 108 is applied on the drain and gate of each of the control NMOSFETs in all of the drivers 120, 121, . . . , and 127.

Operation for driving one of the word lines WL0, WL1, . . . , and WL7 to a boost voltage VPXG is now described in reference to FIGS. 3 and 4. FIG. 3 shows one of the drivers 120, 121, . . . , and 127 coupled between the global X-decoder 108 and the vertical word line decoder 112. The vertical word line decoder 112 further includes a high voltage pump 152 and a high voltage switch 154. The high voltage pump 152 generates the boost voltage VPXG, and the high voltage switch 154 switches between one of the boost voltage VPXG or the low voltage VSS to be applied as the word line voltage VWL at the drain of the driving NMOSFET 132.

Referring to FIGS. 3 and 4, for driving one of the word lines WL0, WL1, . . . , and WL7 to the boost voltage VPXG, the controls signal GWL is set to a logical high state (and the control signal NWL is set to a logical low state) at time point T1. Thus at time point T1, the pass NMOSFET 136 and the driving NMOSFET 132 are turned on, and the pull-down NMOSFET 134 is turned off.

Initially, an ENABLE signal to the high voltage switch 154 is at the logical low state to control the high voltage switch 154 to couple the low voltage VSS as the word line voltage VWL applied at the drain of the driving NMOSFET 132. Thus, an output word line voltage WL is also at the logical low state at time point T1. In addition, a control voltage BSTR that is approximately GWL-V_{TH} is developed at the gate of the driving NMOSFET 132, with V_{TH} being the threshold voltage of the pass NMOSFET 136.

Thereafter at time point T2, the ENABLE signal is asserted to the logical high state to control the high voltage switch 154 to couple the boost voltage VPXG as the word line voltage VWL applied at the drain of the driving NMOSFET 132. In that case, the output word line voltage WL eventually reaches the boost voltage VPXG after time point T2. In addition, the control voltage BSTR is further boosted eventually to (GWL-V_{TH})+A*VWL at the gate of the driving NMOSFET 132, with A being a ratio of capacitances for the NMOSFETs 132 and 134.

Referring to FIG. 4, when the high voltage switch 154 switches to apply the boost voltage VPXG from the low voltage VSS as the word line voltage VWL, the boost voltage VPXG generated from the high voltage pump 152 has voltage dipping 156 shortly after time point T2 from parasitic capacitances. Such parasitic capacitances may be significant if a large area of metal is coupled to the word line driven to the output word line voltage WL and/or if the word line voltage VWL is desired to be applied across a large number of blocks of the flash memory device.

The parasitic capacitances sink charge and cause initial current flow from the drain of the driving transistor 132 when the high voltage switch 154 switches to apply the boost voltage VPXG from the low voltage VSS as the word line voltage VWL at time point T2. Thus, significant voltage dipping 156 is observed in the boost voltage VPXG from the high voltage pump 152. Such voltage dipping 156 disadvantageously slows down the charging of the output word line voltage WL to the boost voltage VPXG. Thus, the rise-time of the output word line voltage WL to the boost voltage VPXG is increased causing a slow-down in operation of the local X-decoder 106.

A mechanism is desired for preventing such voltage dipping 156 at the high voltage pump 152.

### SUMMARY OF THE INVENTION

Accordingly, a loading capacitor is formed at the high voltage pump for preventing voltage dipping.

In one embodiment of the present invention, a decoder system for a memory device includes a high voltage pump, a high voltage switch, and a loading capacitor. The high voltage pump generates a boost voltage, and the high voltage switch couples one of the boost voltage or a low voltage to a line of the memory device. The loading capacitor is coupled to a node between the high voltage pump and the high voltage switch. The loading capacitor minimizes voltage dipping of the boost voltage that is switched to be applied on the line of the memory device.

In another embodiment of the present invention, the decoder system further includes a local decoder for coupling one of the boost voltage or the low voltage from the high voltage switch to the line of the memory device. In addition, the decoder system includes a global decoder for generating control signals. In that case, the local decoder couples one of the boost voltage or the low voltage to the line of the memory device in response to the control signals.

In an example embodiment of the present invention, each local decoder includes a driving transistor and a pass transistor. The driving transistor is coupled between the high voltage switch and the line of the memory device and receives one of the boost voltage or the low voltage. The pass transistor is coupled between the global decoder and the driving transistor and turns on the driving transistor to couple one of the boost voltage or the low voltage to the line of the memory device in response to the control signals.

In another embodiment of the present invention, each local decoder further includes a pull-down transistor coupled between a low voltage supply, the line of the memory device, and the global decoder. The pull-down transistor is turned on to couple the low voltage of the low voltage supply to the line of the memory device when the driving transistor is turned off in response to the control signals.

In another example embodiment of the present invention, a capacitance of the loading capacitor is about four times a parasitic capacitance at the line of the memory device. In that case, the voltage dipping of the boost voltage may be reduced by about 75%.

In a further embodiment of the present invention, the decoder system further includes a loading resistor coupled to the node between the high voltage pump and the high voltage switch. Such a loading resistor slows down the voltage dipping of the boost voltage.

The present invention may be applied to particular advantage when the line of the memory device is a word-line of a flash memory device. However, the present invention may also be applied for charging other types of nodes in other types of memory devices with minimized voltage dipping.

### BRIEF DESCRIPTION OF THE DRAWINGS

These and other features and advantages of the present invention will be better understood by considering the following detailed description of the invention, which is presented with the attached drawings in which:

FIG. 1 shows basic elements of a flash memory device including a local X-decoder for driving word lines, according to the prior art;

FIG. 2 shows a circuit diagram of an example local X-decoder with a respective pass NMOSFET coupled to a respective driving NMOSFET for each word line, according to the prior art;

FIG. 3 shows components of an example driver in the local X-decoder of FIG. 2 for switching between a boost voltage and a low voltage to be applied on a word line, according to the prior art;

FIG. 4 shows a timing diagram of signals during operation of the components of FIG. 3, according to the prior art;

FIG. 5 shows components of an example decoder system in a local X-decoder with minimized voltage dipping of a boost voltage, according to an embodiment of the present invention;

FIG. 6 shows a timing diagram of signals during operation of the components of FIG. 5, according to an embodiment of the present invention;

FIG. 7 shows components of FIG. 5 with a loading capacitor being implemented with an NMOSFET, according to an embodiment of the present invention; and

FIG. 8 shows components of FIG. 5 but further including a loading resistor for slowing down voltage dipping of the boost voltage, according to an embodiment of the present invention.

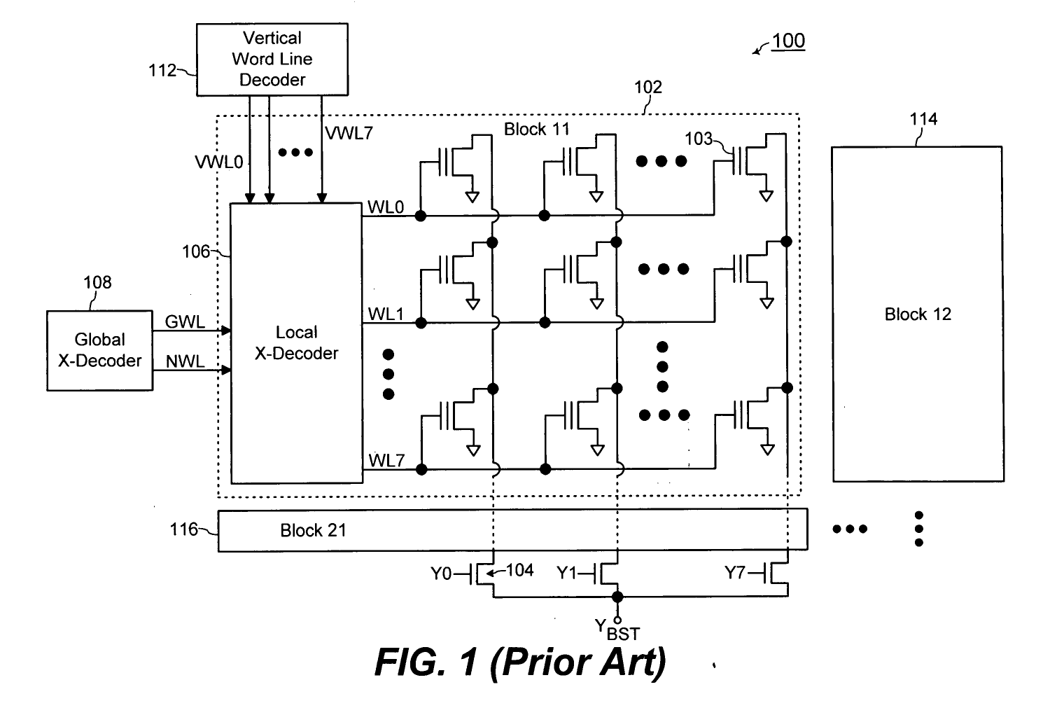

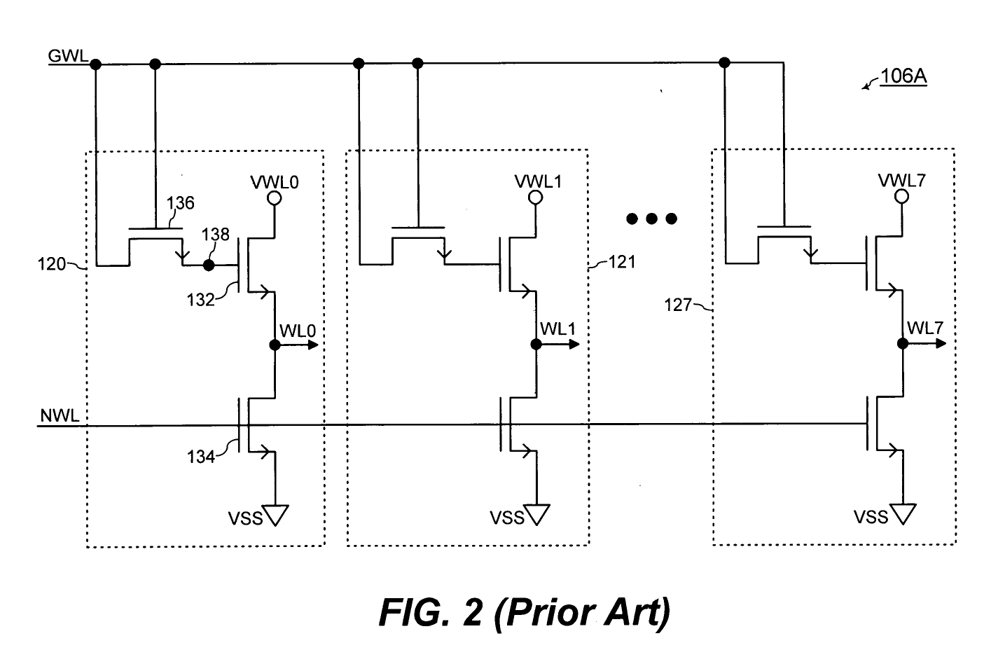

The figures referred to herein are drawn for clarity of illustration and are not necessarily drawn to scale. Elements having the same reference number in FIGS. 1, 2, 3, 4, 5, 6, 7, and 8 refer to elements having similar structure and/or function.

### DETAILED DESCRIPTION

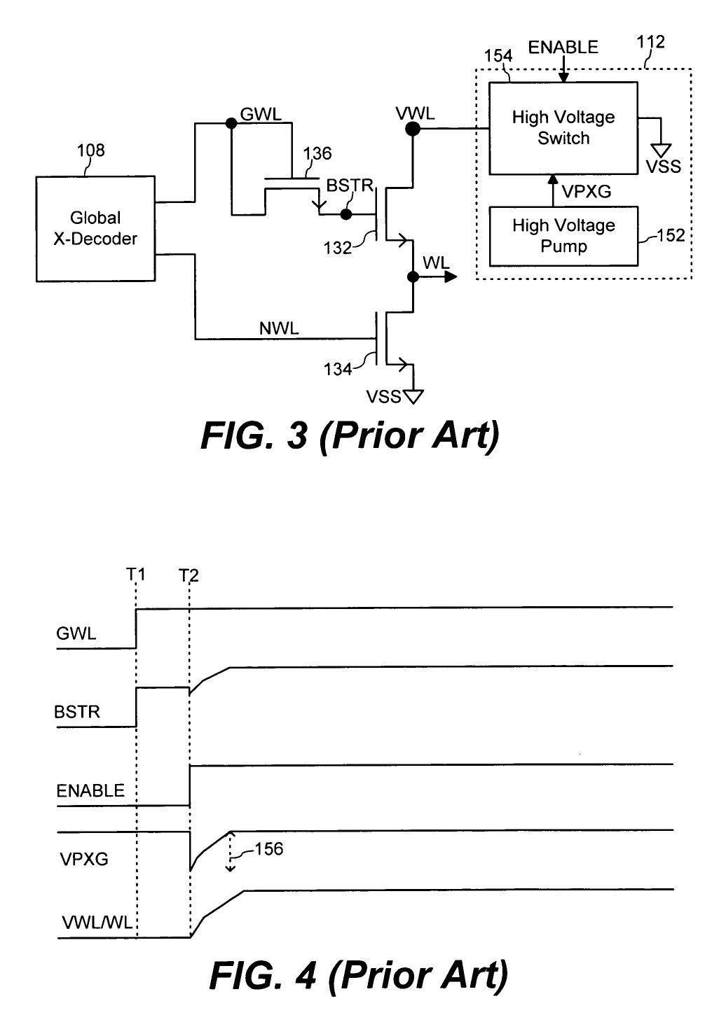

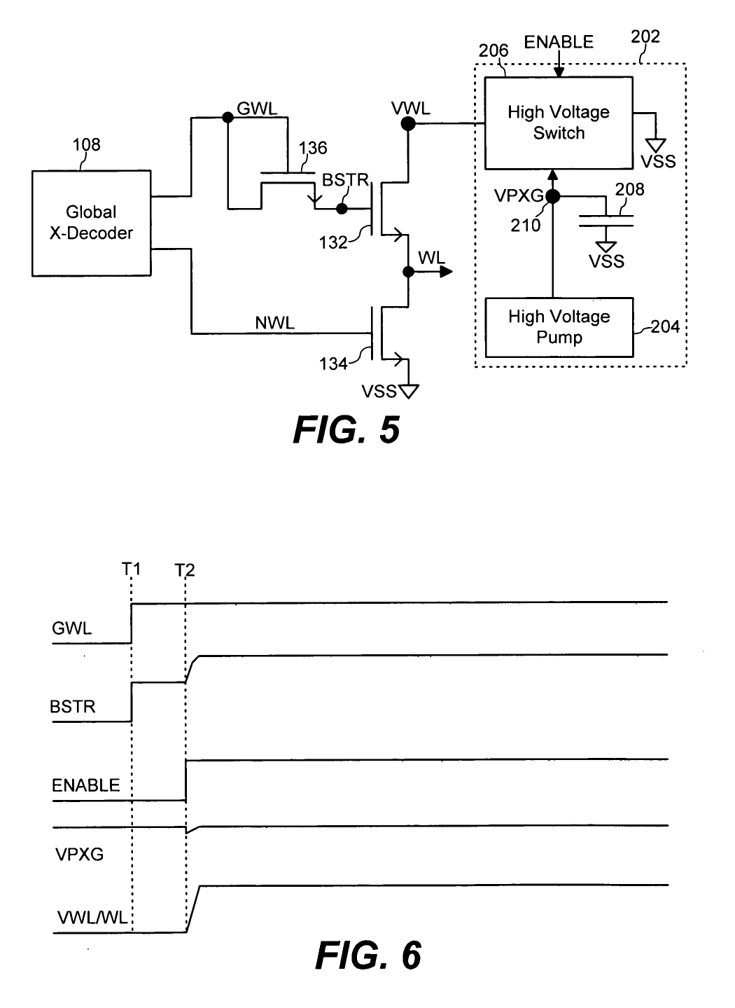

FIG. 5 shows components of an example decoder system in a local X-decoder with minimized voltage dipping of a boost voltage, according to an embodiment of the present invention. The global X-decoder 108, the pass NMOSFET 136, the driving NMOSFET 132, and the pull-down NMOSFET 134 operate and are configured similarly as described in reference to FIG. 3.

A vertical word line decoder 202 of FIG. 5 however is different from that of FIG. 3. The vertical word line decoder 202 of FIG. 5 includes a high voltage pump 204, a high voltage switch 206, and a loading capacitor 208 coupled at a node 210 between the high voltage pump 204 and the high voltage switch 206. In one embodiment of the present invention, the loading capacitor 208 has a first node coupled to the node 210 between the high voltage pump 204 and the high voltage switch 206 and a second node coupled to the low voltage supply.

The high voltage pump 204 generates the boost voltage VPXG. The high voltage switch 154 switches between one of the boost voltage VPXG or the low voltage VSS of the low voltage supply to be applied as the word line voltage VWL at the drain of the driving NMOSFET 132. For example, when an ENABLE signal is set to a logical low state, the high voltage switch 154 is switched to couple the low voltage VSS as the word line voltage VWL applied at the drain of the driving NMOSFET 132. Alternatively, when the ENABLE signal is set to a logical high state, the high voltage switch 154 is switched to couple the boost voltage VPXG from the high voltage pump 204 as the word line voltage VWL applied at the drain of the driving NMOSFET 132.

Operation of the decoder system of FIG. 5 is now described in reference to the timing diagram of FIG. 6. Referring to FIGS. 5 and 6, for driving the output word line voltage WL to the boost voltage VPXG, the controls signal GWL is set to a logical high state (and the control signal NWL is set to a logical low state) at time point T1. Thus at time point T1, the pass NMOSFET 136 and the driving NMOSFET 132 are turned on, and the pull-down NMOSFET 134 is turned off.

Initially, the ENABLE signal is set at the logical low state to control the high voltage switch 154 to couple the low voltage VSS as the word line voltage VWL applied at the drain of the driving NMOSFET 132. Thus, the output word line voltage WL is also at the logical low state at time point T1. In addition, a control voltage BSTR that is approximately GWL-V_{TH} is developed at the gate of the driving NMOSFET 132, with V_{TH} being the threshold voltage of the pass NMOSFET 136.

Thereafter at time point T2, the ENABLE signal is asserted to the logical high state to control the high voltage switch 154 to couple the boost voltage VPXG as the word line voltage VWL applied at the drain of the driving NMOSFET 132. In that case, the output word line voltage WL eventually reaches the boost voltage VPXG after time point T2. In addition, the control voltage BSTR is further boosted eventually to (GWL-V_{TH})+A*VWL at the gate of the driving NMOSFET 132, with A being a ratio of capacitances for the NMOSFETs 132 and 134. The ENABLE signal is at the logical low state or the logical high state depending on address decoding which indicates whether a particular word line for WL is desired to be accessed.

Further referring to FIG. 6, when the high voltage switch 154 switches to apply the boost voltage VPXG from the low voltage VSS as the word line voltage VWL at time point T2, the boost voltage VPXG generated from the high voltage pump 152 has minimized voltage dipping of the boost voltage VPXG shortly after time point T2 because of the presence of the loading capacitor 208. Such loading capacitor 208 has charge stored thereon before the time point T2. Then, at time point T2, such charge stored on the loading capacitor 208 charges up parasitic capacitance coupled to the node 210 to minimize the voltage dipping of the boost voltage VPXG.

In one example embodiment of the present invention, the capacitance of the loading capacitor 208 is about four times a total parasitic capacitance coupled to the node 210. In that case, the voltage dipping of the boost voltage VPXG is reduced by about 75%. Further referring to FIG. 6, with such minimized voltage dipping of the boost voltage VPXG, the output word line voltage WL is charged up to the boost voltage VPXG advantageously with a faster rise time than in FIG. 4.

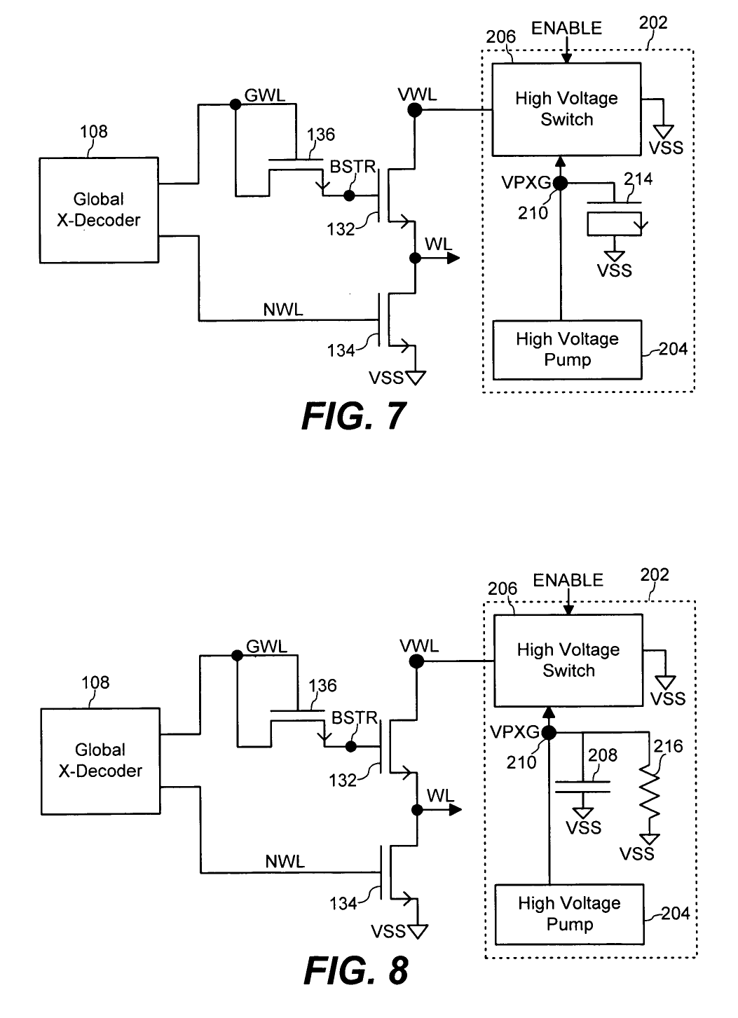

FIG. 7 is similar to FIG. 5, but the loading capacitor at the node 210 is implemented as an NMOSFET (N-channel metal oxide semiconductor field effect transistor) 214. The gate of the NMOSFET 214 is coupled to the node 210, and the drain and source of the NMOSFET 214 are coupled to the low voltage source. The decoding system of FIG. 7 operates similarly to that of FIG. 5. The present invention may also be practiced with any other implementations for the loading capacitor 208 such as a high voltage capacitor or a metal oxide capacitor.

FIG. 8 is similar to FIG. 5, but a loading resistor 216 is also coupled to the node 210. One end of the loading resistor 216 is coupled to the node 210, and the other end is coupled to the low voltage source. Such a loading resistor 216 with the loading capacitor 208 provide a RC time constant for slowing down voltage dipping of the boost voltage VPXG at the node 210. Otherwise, the decoding system of FIG. 8 operates similarly to that of FIG. 5.

In this manner, the decoding system of the present invention uses a loading capacitor at the node 210 having the boosting voltage VPXG generated thereon for minimizing voltage dipping of the boost voltage VPXG. Such minimized voltage dipping increase the rise time of the output word line voltage WL to the boost voltage VPXG for faster operation of the decoding system. Such a decoding system may be particularly advantageous when the word line that is charged to the boost voltage VPXG is within a flash memory device having one of an ORNAND, NAND, or NOR architecture. However, the present invention may also be applied for any types of flash memory architecture, and any types of memory devices.

Thus, the foregoing is by way of example only and is not intended to be limiting. For example, any materials, parameter values, or number of elements shown or described herein are by way of example only.

1. A decoder system for a memory device, the decoder system comprising:
a voltage pump for generating a boost voltage;
a voltage switch for coupling one of the boost voltage or a low voltage to a line of the memory device wherein the boost voltage has a higher voltage magnitude than the low voltage; and
a loading capacitor coupled to a node between the voltage pump and the voltage switch,
wherein the loading capacitor is a separate additional capacitor from any capacitor of the voltage pump such that a capacitance of the loading capacitor is determined by a parasitic capacitance at said line of the memory device.

2. The decoder system of claim 1, wherein the loading capacitor minimizes voltage dipping of the boost voltage that is switched to be applied on the line of the memory device.

3. The decoder system of claim 1, further comprising:
a local decoder for coupling one of the boost voltage or the low voltage from the voltage switch to the line of the memory device.

4. The decoder system of claim 3, further comprising:
a global decoder for generating control signals, wherein the local decoder couples one of the boost voltage or the low voltage to the line of the memory device in response to the control signals.

5. The decoder system of claim 4, wherein each local decoder includes:
a driving transistor, coupled between the voltage switch and the line of the memory device, for receiving one of the boost voltage or the low voltage; and
a pass transistor, coupled between the global decoder and the driving transistor, for turning on the driving transistor to couple one of the boost voltage or the low voltage to the line of the memory device in response to the control signals.

6. The decoder system of claim 5, wherein each local decoder further includes:
a pull-down transistor, coupled between a low voltage supply, the line of the memory device, and the global decoder, wherein the pull-down transistor is turned on to couple the low voltage of the low voltage supply to the line of the memory device when the driving transistor is turned off in response to the control signals.

7. The decoder system of claim 1, wherein the line of the memory device is a word-line of a flash memory device.

8. The decoder system of claim 1, wherein a capacitance of the loading capacitor is about four times the parasitic capacitance at the line of the memory device.

9. The decoder system of claim 1, further comprising:
a loading resistor coupled to the node between the voltage pump and the voltage switch,
wherein the loading resistor is a separate additional resistor from any resistor of the voltage pump.

10-14. (canceled)

15. A method for driving a line of a memory device, comprising:
generating a boost voltage from a voltage pump;
charging a loading capacitor coupled to the voltage pump when a low voltage is coupled to the line of the memory device, wherein the boost voltage has a higher voltage magnitude than the low voltage; and
coupling the loading capacitor to the line of the memory device when the voltage pump is switched to be applied on the line of the memory device,
wherein the loading capacitor is a separate additional capacitor from any capacitor of the voltage pump such that a capacitance of the loading capacitor is determined by a parasitic capacitance at said line of the memory device.

16. The method of claim 15, wherein the coupling of the loading capacitor minimizes voltage dipping of the boost voltage that is switched to be applied on the line of the memory device.

17. The method of claim 16, further comprising:
slowing down the voltage dipping of the boost voltage that is switched to be applied on the line of the memory device.

18. The method of claim 15, further comprising:
coupling one of the boost voltage or the low voltage to the line of the memory device in response to control signals from a global decoder.

19. The method of claim 15, wherein the line of the memory device is a word-line in a flash memory device.

20. The method of claim 15, wherein a capacitance of the loading capacitor is about four times the parasitic capacitance at the line of the memory device.
